(19) United States
(12) Patent Application Publication
(10) Pub. No.: US 2016/0300757 A1
(43) Pub. Date: Oct. 13, 2016

(54) DIELECTRIC CONSTANT RECOVERY

(71) Applicant: Applied Materials, Inc., Santa Clara, CA (US)

(72) Inventors: Priyanka Dash, Menlo Park, CA (US); Deenesh Padhi, Sannyvale, CA (US)

(73) Assignee: Applied Materials, Inc., Santa Clara, CA (US)

(21) Appl. No.: 15/083,977

(22) Filed: Mar. 29, 2016

Related U.S. Application Data
(60) Provisional application No. 62/144,256, filed on Apr. 7, 2015.

(51) Int. Cl. H01L 21/768

(52) U.S. Cl. CPC H01L 21/76808; H01L 21/76816; H01L 21/76877; H01L 21/76831

(57) ABSTRACT

A method of forming features in a low-k dielectric layer on a patterned substrate is described. A via, trench or a dual damascene structure may be formed in the low-k dielectric layer. Patterning the low-k dielectric layer may also increase the dielectric constant. The patterned substrate is processed by shining UV-light on the low-k dielectric layer while exposing the low-k dielectric layer to a carbon-and-hydrogen-containing precursor to restore or lower the dielectric constant. Then, a conformal hermetic layer is formed on the low-k dielectric layer. The conformal hermetic layer is configured to keep water and contaminants out of the low-k dielectric layer during later processing and during the lifespan of the completed device.

### FIELD

Embodiments of this disclosure relate to low-k dielectric materials.

### BACKGROUND

Low-k dielectrics have a smaller dielectric constant than silicon dioxide (SiO₂). Silicon dioxide has a dielectric constant of 3.9. Low-k dielectric materials are positioned between conducting elements in integrated circuits to improve achievable switching speed and reduce power consumption as feature sizes are decreased. Low-k dielectric films are achieved by selecting film materials which reduce dielectric constant and/or inserting pores inside the film.

The conductivity of the conducting elements (e.g. metal lines) can be increased to further improve performance. As a consequence, copper has replaced many other metals for longer lines (interconnects). Copper has a lower resistivity and higher current carrying capacity. However, precautions must be taken to discourage diffusion of copper into surrounding materials. Besides the need to inhibit diffusion into active semiconductor areas, copper should be kept from entering porous low-k dielectric regions to avoid shorting and/or raising the dielectric constant.

An example of an integrated circuit structure which implements copper as an interconnect material is a dual damascene structure. In a dual damascene structure, the dielectric layer is etched to define both the contacts/vias and the interconnect lines. Metal is inlaid into the defined pattern and any excess metal is removed from the top of the structure in a planarization process, such as chemical mechanical polishing (CMP).

Novel liner layers and/or process modifications are needed to achieve high conductivity for the interconnect connections in combination with a low-k for the dielectric material.

### SUMMARY

A method of forming features in a low-k dielectric layer on a patterned substrate is described. A via, trench or a dual damascene structure may be formed in the low-k dielectric layer. Patterning the low-k dielectric layer may also increase the dielectric constant. The patterned substrate is processed by shining UV-light on the low-k dielectric layer while exposing the low-k dielectric layer to a carbon-and-hydrogen-containing precursor to restore or lower the dielectric constant. Then, a conformal hermetic layer is formed on the low-k dielectric layer. The conformal hermetic layer is configured to keep water and contaminants out. Some of the same conformal hermetic layer may deposit on the underlying copper. The portion of the conformal hermetic layer on the underlying copper may be preferentially removed but the beneficial portion on the low-k dielectric layer remains. The selective removal of the conformal hermetic layer may be accomplished using a dry etch or a wet etch using a weak organic acid.

Embodiments described herein include methods of forming a patterned substrate. The methods include placing the patterned substrate having a patterned low-k dielectric layer into a substrate processing region. The patterned substrate includes a gap through the patterned low-k dielectric layer to an underlying metal layer. The gap has dielectric sidewalls in the patterned low-k dielectric layer. The methods further include flowing a carbon-and-hydrogen-containing precursor in the substrate processing region while shining UV-light onto the patterned low-k dielectric layer. The methods further include forming a conformal hermetic layer on the patterned substrate by flowing the carbon-and-hydrogen-containing precursor. The methods further include depositing gapfill copper into the gap to form a conducting contact between the gapfill copper and the underlying metal layer.

Forming the conducting contact may include depositing gapfill copper into the gap. The conformal hermetic layer may include silicon, carbon and nitrogen. The thickness of the conformal hermetic layer may be between 0.1 nm and 0.3 nm. The conformal hermetic layer may be configured to prevent moisture from entering the dielectric sidewalls. The conformal hermetic layer may be configured to prevent metal atoms from migrating into the dielectric sidewalls. The carbon-and-hydrogen-containing precursor may include flowing a silicon-carbon-and-hydrogen-containing precursor in the substrate processing region. The silicon-carbon-and-hydrogen-containing precursor in the substrate processing region may reduce a dielectric constant of the patterned low-k dielectric layer below 2.4. Flowing the silicon-carbon-and-hydrogen-containing precursor in the substrate processing region may remove hydroxyl groups from the low-k dielectric layer and may adsorb CxHy groups.

Embodiments described herein include methods of forming a gap in a low-k dielectric layer. The methods include removing —OH groups from the low-k dielectric layer and replacing them with CxHy groups to reduce a dielectric constant of the low-k dielectric layer. The methods further include forming a conformal silicon-carbon-and-nitrogen-containing layer on a patterned substrate. The patterned substrate includes the gap above an underlying copper layer. Sidewalls of the gap include low-k dielectric material. The conformal silicon-carbon-and-nitrogen-containing layer is configured to prevent diffusion of material into the low-k dielectric material. The methods further include depositing a conductor into the gap to form an electrical contact between the conductor and the underlying copper layer.

The methods may further include removing a portion of the conformal silicon-carbon-and-nitrogen-containing layer on the underlying copper layer before depositing the conductor into the gap. The conformal silicon-carbon-and-nitrogen-containing layer may consist of silicon, carbon and hydrogen. The conductor may include cobalt or copper. A width of the gap may be less than 20 nm.

Embodiments described herein include methods of forming a dual damascene structure. The methods include forming a methylation layer on the dual damascene structure. The methods further include forming a conformal silicon carbon nitride layer over a patterned substrate. The patterned substrate include a trench and a via below the trench. The via is above an underlying copper layer. Sidewalls of the trench and the via include low-k dielectric walls. The trench is fluidly coupled to the via and the conformal silicon carbon nitride layer forms a hermetic seal between the trench and the low-k dielectric walls. A width of the via may be less than 50 nm. A width of the trench may be less than 70 nm.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### DESCRIPTION OF THE DRAWINGS

A further understanding of the nature and advantages of the embodiments may be realized by reference to the remaining portions of the specification and the drawings.

FIG. 1 is a flow chart of a low-k dielectric treatment process according to embodiments.

FIGS. 2A, 2B, 2C, 2D and 2E show cross-sectional views of a device at stages of a low-k dielectric treatment process according to embodiments.

FIG. 3 is a schematic representation of a substrate processing chamber used to perform selected operations of low-k dielectric treatment process according to embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

A method of forming features in a low-k dielectric layer on a patterned substrate is described. A via, trench or a dual damascene structure may be formed in the low-k dielectric layer. Patterning the low-k dielectric layer may also increase the dielectric constant. The patterned substrate is processed by shining UV-light on the low-k dielectric layer while exposing the low-k dielectric layer to a carbon-and-hydrogen-containing precursor to restore or lower the dielectric constant. Then, a conformal hermetic layer is formed on the low-k dielectric layer. The conformal hermetic layer is configured to keep water and contaminants out. Some of the same conformal hermetic layer may deposit on the underlying copper. The portion of the conformal hermetic layer on the underlying copper may be preferentially removed but the beneficial portion on the low-k dielectric layer remains. The selective removal of the conformal hermetic layer may be accomplished using a dry etch or a wet etch using a weak organic acid.

Copper damascene and dual-damascene structures have been used for several decades and involve depositing copper into gaps in a patterned low-k dielectric layer. Dual damascene structures include two distinct patterns formed into a dielectric layer. The lower pattern may include via structures whereas the upper pattern may include a trench. The low-k dielectric layer may exhibit an increase in the dielectric constant during the patterning to form the via and/or the trench as a result of the exposure to etchants or other chemicals/processing. Methods described herein lower the dielectric constant prior to depositing any further layers, which might “lock in” the raised dielectric constant. A conformal hermetic layer may then be deposited covering the patterned low-k dielectric layer. The conformal hermetic layer on the low-k dielectric layer may prevent subsequent diffusion into the low-k dielectric layer. The conformal hermetic layer may prevent subsequent rises in dielectric constant as well. The via and the trench are then filled at the same time which is the operation for which the dual-damascene process gets its name.

The methods described herein provide the benefit of achievement and maintenance of low dielectric constant in the patterned low-k dielectric layer which increases performance of completed devices (e.g. higher switching speeds or lower power consumption). The methods described herein also provide the benefit of increasing the longevity of completed devices. The longevity may be characterized by applying a large DC voltage across the low-k dielectric and measuring the current passing through to detect the moment of breakdown. The benefit of increased longevity may result from a decrease in electromigration which helps to sustain a high conductivity in metal portions of the completed integrated circuit.

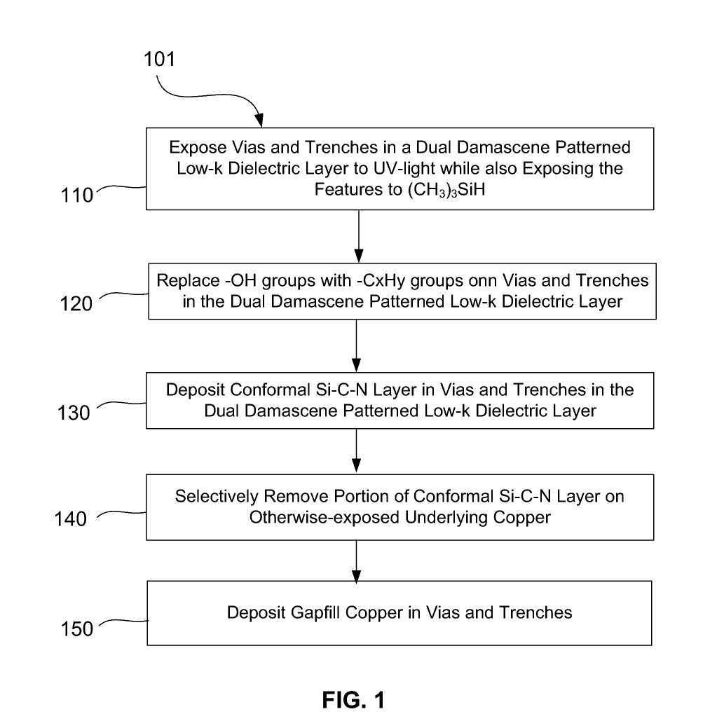

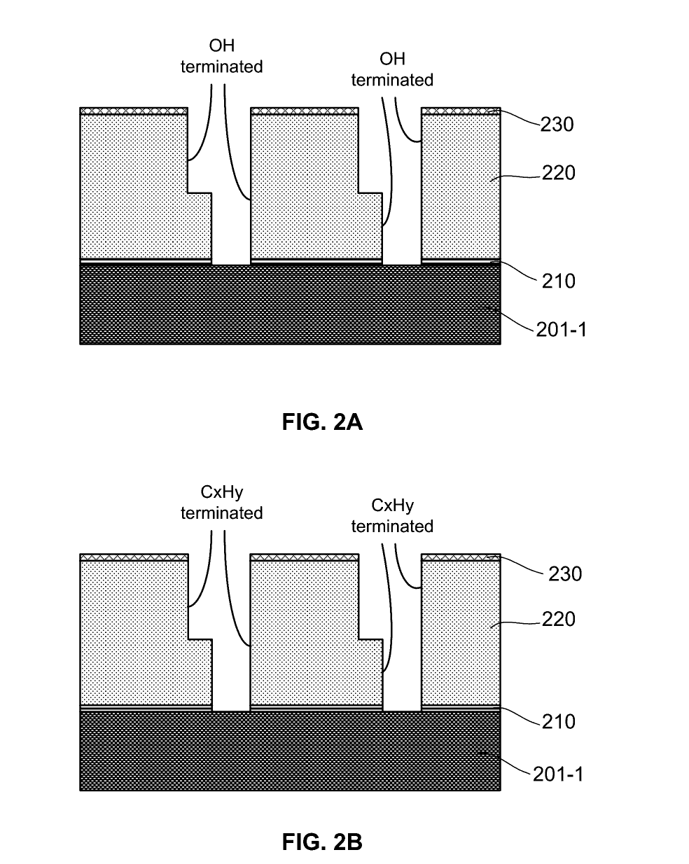

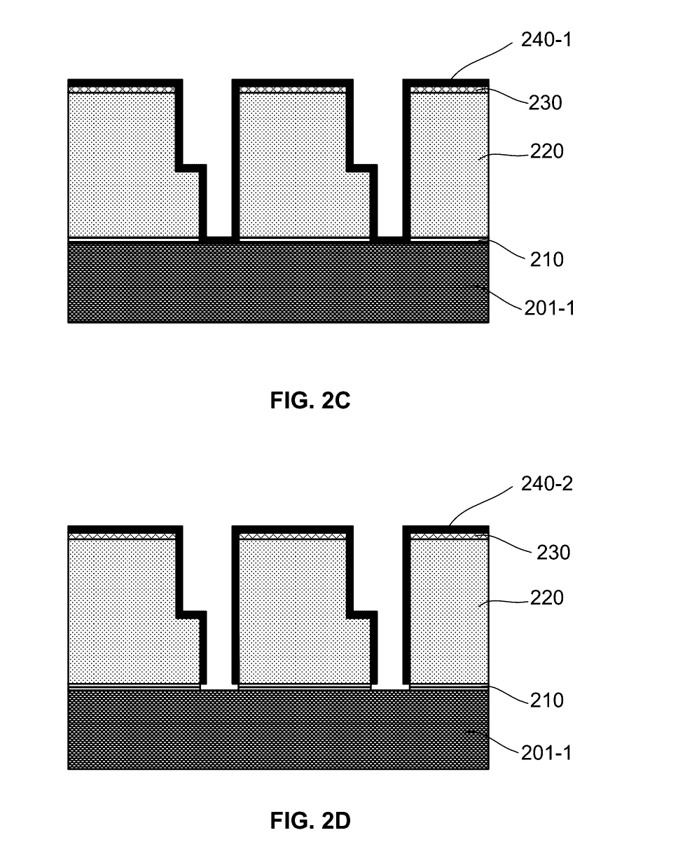

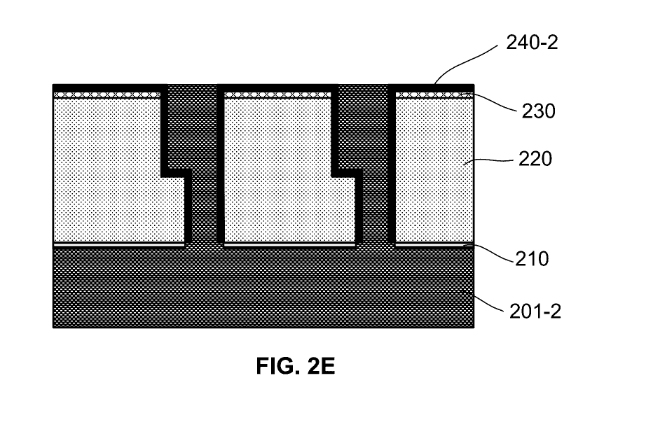

To better understand and appreciate the embodiments herein, reference is now made to FIG. 1 which is a low-k dielectric treatment process 101 according to embodiments. Reference may concurrently be made to FIGS. 2A, 2B, 2C, 2D and 2E which show cross-sectional views of a device at various stages of low-k dielectric treatment process 101. The portion of the device shown may be a back-end of the line (BEOL) interconnect portion of an integrated circuit during formation in embodiments. Prior to the first operation (FIG. 2A), an exposed titanium nitride layer is formed, patterned into titanium nitride hardmask 230, and used to pattern an underlying low-k dielectric layer 220 on a patterned substrate. A copper barrier dielectric layer 210 may be used to physically separate underlying copper layer 201-1 from low-k dielectric layer 220. Underlying copper layer 201-1 is located beneath the low-k dielectric layer and is exposed to the atmosphere through the combination of the via and the trench. Generally speaking, underlying copper layer 201-1 may be an underlying metal layer.

Low-k dielectric layer 220 may have pores within the film to achieve a lower dielectric constant than silicon oxide. Low-k dielectric layer 220 may comprise or consist of silicon, carbon and oxygen, in embodiments, to further reduce the dielectric constant below that of silicon oxide. Low-k dielectric layer 220 may therefore be referred to as silicon oxycarbide. Low-k dielectric treatment process 101 has been developed to achieve and maintain a low dielectric constant within low-k dielectric layer 220 during processing and during the active life of the integrated circuit produced.

Titanium nitride hardmask 230 may be physically separated from low-k dielectric layer 220 by an auxiliary hardmask to facilitate processing, though no such layer is shown in FIGS. 2A, 2B, 2C, 2D or 2E. The auxiliary hardmask layer may be a silicon oxide hardmask in embodiments. “Top”, “above” and “up” will be used herein to describe portions/directions perpendicularly distal from the substrate plane and further away from the center of mass of the substrate in the perpendicular direction. “Vertical” will be used to describe items aligned in the “up” direction towards the “top”. Other similar terms may be used whose meanings will now be clear.

The patterned substrate may be placed in a substrate processing region of a substrate processing chamber. Low-k dielectric treatment process 101 begins in operation 110, wherein a carbon-and-hydrogen-containing precursor is flowed in the substrate processing region while a UV-light is shined upon low-k dielectric layer 220. Hydroxyl groups (—OH) may be present on low-k dielectric layer 220 as shown in FIG. 2A prior to operation 110 and the concurrent exposure of low-k dielectric layer 220 to UV-light and the carbon-and-hydrogen-containing precursor may replace the hydroxyl groups with methyl groups or CxHy groups in embodiments (operation 120). Operation 120 may also result in the formation of covalent bonds within low-k dielectric layer 220, for example, Si—O—Si bridge bonds may be formed in embodiments. Operation 120 may be referred to as methylation and results in a lowering of the dielectric constant within low-k dielectric layer 220. Adsorbed CxHy groups are shown on low-k dielectric layer 220 in FIG. 2B.

There are specific traits of the carbon-and-hydrogen-containing precursor which may promote the effectiveness of the methylation process. Examples and traits are effective and suitable precursors are now provided. The carbon-and-hydrogen-containing precursor may comprise one or more of benzene (C₆H₆) or toluene (CH₃C₆H₅) according to embodiments. The carbon-and-hydrogen-containing precursor may possess fewer than seven carbon atoms in embodiments. The carbon-and-hydrogen-containing precursor may comprise or consist of carbon and hydrogen according to embodiments. The carbon-and-hydrogen-containing precursor may further comprise silicon and be referred to as a silicon-carbon-and-hydrogen-containing precursor. The silicon-carbon-and-hydrogen-containing precursor may comprise or consist of silicon, carbon and hydrogen in embodiments. The silicon-carbon-and-hydrogen-containing precursor may comprise or consist of silicon, carbon, nitrogen and hydrogen according to embodiments. The silicon-carbon-and-hydrogen-containing precursor may comprise one or more of (CH₃)₄Si, (CH₃)₃SiH, (CH₃)₂SiH₂, (CH₃)SiH₃, (CH₃)₃Si(N(CH₃)₂), (CH₃)₂Si(N(CH₃)₂)₂, (CH₃)Si(N(CH₃)₂)₃, or Si(N(CH₃)₂)₄, in embodiments. The size of the molecules may correlate with the effectiveness of UV-light in causing the reduction of dielectric constant. The silicon-carbon-and-hydrogen-containing precursor may possess one silicon atom and fewer than six, fewer than seven, fewer than eight or fewer than nine carbon atoms according to embodiments.

A conformal hermetic layer 240-1 is formed on the patterned substrate in operation 130, shown following formation in FIG. 2C. Operations 110 and 120 may occur concurrently, but operation 130 occurs after both operations 110 and 120. Operations 110 and 120 occur within the same substrate processing region as one another. Furthermore, operation 130 may occur within the same substrate processing region as well in embodiments. Therefore, the patterned substrate need not be moved during operations 110 through 130. Conformal hermetic layer 240-1 is conformal over the features of the patterned substrate and contacts underlying copper layer 201-1 directly in embodiments. The conformal hermetic layer may also contact low-k dielectric layer 220 directly, according to embodiments, aside from the thin adsorbate layer applied during treatment 120. Conformal hermetic layer 240-1 may protect the lowered dielectric constant of low-k dielectric layer 220 against undesirable increases later on. Conformal hermetic layer 240-1 may be a silicon-carbon-and-nitrogen-containing layer in embodiments. Conformal hermetic layer 240-1 may comprise or consist of silicon, carbon and nitrogen, according to embodiments, and may be referred to as silicon carbon nitride or Si—C—N. Conformal hermetic layer 240-1 may inhibit diffusion of subsequently-introduced etchants or moisture and may therefore protect the integrity of low-k dielectric layer 220 during and after processing in embodiments. A copper barrier dielectric layer 210 may be positioned between underlying copper layer and low-k dielectric layer 220 as shown in FIGS. 2A, 2B, 2C, 2D, and 2E. The deposition process of conformal hermetic layer 240-1 may also result in an additional lowering of the dielectric constant from additional displacement of absorbates and other components within low-k dielectric layer 220. Conformal hermetic layer 240-1 (and conformal hermetic layer 240-2 later) may help to avoid diffusion of copper into low-k dielectric layer 220 as well, according to embodiments.

Conformal hermetic layer (e.g. Si—C—N) is exposed to a weak acid in operation 140. Conformal hermetic layer 240-1 is etched back to expose underlying copper layer 201-1, shown following the operation in FIG. 2D. Selective etching operation 140 may involve liquid or gas-phase etchants according to embodiments. A process which uses gas-phase etchants may be referred to herein as a dry-etch and etching operations within a dry-etch may be referred to as dry-etching conformal hermetic layer 240-1. After selective etching operation 130 a portion of conformal hermetic layer 240-1 remains and will be referred to as conformal hermetic layer 240-2 as shown in FIG. 2D. Conformal hermetic layer 240-2 may also be referred to as the remaining portion of conformal hermetic layer 240-1. Conformal hermetic layer 240-2 continues to seal low-k dielectric layer 220 from environmental influences such as subsequently introduced reactants or moisture which may get into pores in low-k dielectric layer 220 and undesirably increase the dielectric constant. Conformal hermetic layer 240-2 may be a “leave-on” film, according to embodiments, which means conformal hermetic layer 240-2 may remain in the completed integrated circuit being formed in low-k dielectric treatment process 101. Therefore, conformal hermetic layer 240-2 may protect against an increase in dielectric constant within low-k dielectric layer 220 during subsequent processing but also during the operational life of the completed integrated circuit.

The trench and the via may be filled with a conductor (e.g. copper as in the example) to complete the dual-damascene portion of a semiconductor manufacturing process in operation 140. FIG. 2E shows underlying copper 201-2 modified/grown to extend through both the trench and the via. As a result of operations 140, there is no or substantially no thin dielectric interruption which could negatively impact the conductivity within underlying copper 201-2. As a consequence, underlying copper 201-2 is shown as one entity simply extended through the trench and the via. The underlying layer and the gapfill metal grown between the trench and via may be different metals. For example, the gapfill metal may be copper or may be cobalt in embodiments. In the example, FIG. 2E shows underlying copper 201-2 after a planarizing chemical mechanical polishing (CMP) operation since the top surface is flush with the low-k dielectric film stack.

Treatment operations 110/120 may result in an adsorbate layer which on average measures about 0.2 nm and may measure between 0.1 nm and 0.3 nm in embodiments. Treatment operations 110/120 may repair a damaged layer of low-k dielectric layer 220 in which the damage occurred during patterning of the via and/or trench. The damaged layer may be up to 20 nm thick despite the small increase in dimensions as a result of treatment operations 110/120. The total thickness of the low-k dielectric layer may be between 100 nm and 200 nm or between 50 nm and 150 nm according to embodiments. The depth of the effectiveness of the treatment greatly benefits manufacturability of integrated circuits which include low-k dielectric layers.

The thickness of the conformal hermetic layer should be sufficient to form a hermetic seal configured to keep moisture out of the low-k dielectric layer. The thickness should be less than a threshold amount to enable enough conducting material (e.g. copper) to desirably fill the gaps in the patterned low-k dielectric layer and form conducting contacts. The thickness should also be less than a threshold amount to ensure the portion of the conformal hermetic layer on the underlying copper layer is selectively removable. A first portion of the conformal hermetic layer resides on the underlying copper layer following deposition. The thickness of the first portion may be hard to define because growth of the film is splotchy and serves no beneficial purpose on the underlying metal layer. A second portion of the conformal hermetic layer resides on the low-k dielectric layer 220, for example on wall of a gap in the patterned low-k dielectric layer following deposition. The thickness of the second portion of the conformal hermetic layer may be between 0.8 nm and 2.5 nm or between 1.0 nm and 2.0 nm, in embodiments, after deposition but before selective removal. The thickness of the second portion of the conformal hermetic layer may be between 0.7 nm and 2.5 nm or between 0.8 nm and 2.0 nm, in embodiments, after selective removal.

The dielectric constant of low-k dielectric layer 220 may be between 2.4 and 2.9 prior to treatment operations 110 and 120. The dielectric constant of low-k dielectric layer 220 may be below 2.4 or between 2.2 and 2.4 after treatment operation 120 according to embodiments. The dielectric constant of low-k dielectric layer 220 may be reduced by 0.2 or 0.3, in embodiments, by performing treatment operations 110 and 120. Fourier transform infrared spectroscopy (FTIR) was performed before operations 110/120 and after 110/120 to determine the chemical changes to low-k dielectric layer 220. Prior to operations 110/120, detectable peaks were present indicating —OH groups. After operations 110/120, detectable peaks were present indicating Si—CH₃ groups, C—Hx groups, Si—O—Si bonding arrangements and Si—C chemical bonds.

The conformal hermetic layer may be deposited by UV-assisted chemical vapor deposition (UV-CVD) and the deposition process may result in a further reduction of the dielectric constant, possibly by replacing remaining hydroxyl groups on the interior surfaces of pores with methyl groups. The dielectric constant may be reduced by an additional 0.05 or 0.1 simply by depositing conformal hermetic layer 240-1. Conformal hermetic layer 240-1 may be deposited by alternating exposure to ammonia (or NxHy in general) and exposure to a silicon-carbon-nitrogen-and-hydrogen-containing precursor. UV-light may be shone upon low-k-dielectric layer 220 during each of the separate exposures to the nitrogen-and-hydrogen-containing precursor (NxHy). The nitrogen-and-hydrogen-containing precursor may comprise or consist of nitrogen and hydrogen in embodiments. The silicon-carbon-nitrogen-and-hydrogen-containing precursor may comprise or consist of silicon, carbon, nitrogen and hydrogen according to embodiments. The silicon-carbon-nitrogen-and-hydrogen-containing precursor may comprise one or more of (CH₃)₃Si(N(CH₃)₂), (CH₃)₂Si(N(CH₃)₂)₂, (CH₃)Si(N(CH₃)₂)₃, or Si(N(CH₃)₂)₄, in embodiments.

The selective removal operation may remove the first portion but not the second portion of the conformal hermetic layer. The selective removal operation may expose the underlying copper layer in embodiments, or the underlying metal layer in general. This ensures the subsequent capability of achieving a highly conductive connection between the conductor which fills the gaps in the patterned low-k dielectric layer and the underlying copper layer (or, more generally, another underlying metal layer). The contact between the gapfill conductor and the underlying copper layer may be an ohmic contact according to embodiments. The thickness of the second portion of the conformal hermetic layer may be greater than 1.5 nm or greater than 2.0 nm, according to embodiments, after the selective removal operation. The thickness of the second portion of the conformal hermetic layer may be less than 3.0 nm or less than 4.0 nm, in embodiments, after the selective removal operation.

Low-k dielectric layer 220 may have a dielectric constant of between 2.4 and 2.8, between 2.45 and 2.75 or between 2.5 and 2.7 as a result of the patterning of low-k dielectric layer 220 but prior to treatment operations 110/120. Following treatment operations 110/120 the dielectric constant of low-k dielectric layer 220 may be between 2.2 and 2.5, between 2.25 and 2.45, between 2.3 and 2.4, or below 2.4 according to embodiments. Following formation of conformal hermetic layer 240 in operation 130, the lowered dielectric constants are protected against subsequent rises in dielectric constant value and do not rise during subsequent processing or operation in embodiments. After operation 130, the dielectric constant may actually drop a little further and the dielectric constant of low-k dielectric layer 220 may be between 2.1 and 2.4, between 2.15 and 2.35 or between 2.2 and 2.3 according to embodiments.

The trench and/or via structures treated to lower dielectric constant and then lined with the conformal hermetic layer may be a dual-damascene structure including a via underlying a trench. The via may be a low aspect ratio gap and may be, e.g., circular as viewed from above the patterned substrate laying flat. The structure may be at the back end of the line which may result in larger dimensions depending on the device type. A width of the via may be less than 50 nm, less than 40 nm, less than 30 nm or less than 20 nm according to embodiments. A width of the trench may be less than 70 nm, less than 50 nm, less than 40 nm or less than 30 nm in embodiments. The dimensions described herein apply to structures involving a single-patterned low-k dielectric layer (e.g. a single-damascene structure of vias or trenches) or a multi-patterned low-k dielectric layer (e.g. a dual-damascene structure containing vias and trenches). An aspect ratio of the via may be about 1:1, as viewed from above, whereas an aspect ratio of the trench may be greater than 10:1 since the trench is used to contain a conductor meant to electrically attach multiple vias.

The substrate processing region may be plasma-free during all operations described herein. The methylation operations (operations 110 and 120) may be detrimentally affected by a local plasma since methyl (or more generally CxHy groups) may be removed from the surface of low-k dielectric layer 220 by the local plasma. The substrate processing region may also be plasma-free during the formation of conformal hermetic layer 240-1 as well as during selective removal of the first portion of conformal hermetic layer 240-1 residing on underlying metal layer 201-1. The presence of a local plasma during operations 110, 120 and/or 130 may undesirably shrink low-k dielectric layer 220. The presence of a local plasma during operations 110, 120 and/or 130 may also undesirably cause surfaces of low-k dielectric layer 220 to become hydrophilic and therefore sustain additional damage resulting in a rise in dielectric constant.

During treatment, the substrate may be maintained between 180° C. and about 400° C. in general. The temperature of the patterned substrate during operation 110 may be between 200° C. and 385° C., between 200° C. and 300° C., between 300° C. and 385° C. or between 250° C. and 350° C. in embodiments. Higher temperatures within the provided ranges during treatment may result in more shrinkage but lower dielectric constant. Lower temperatures in the ranges provided may result in less shrinkage but higher dielectric constant (less reduction) according to embodiments. The large functional substrate temperature process window is attractive from a manufacturability perspective.

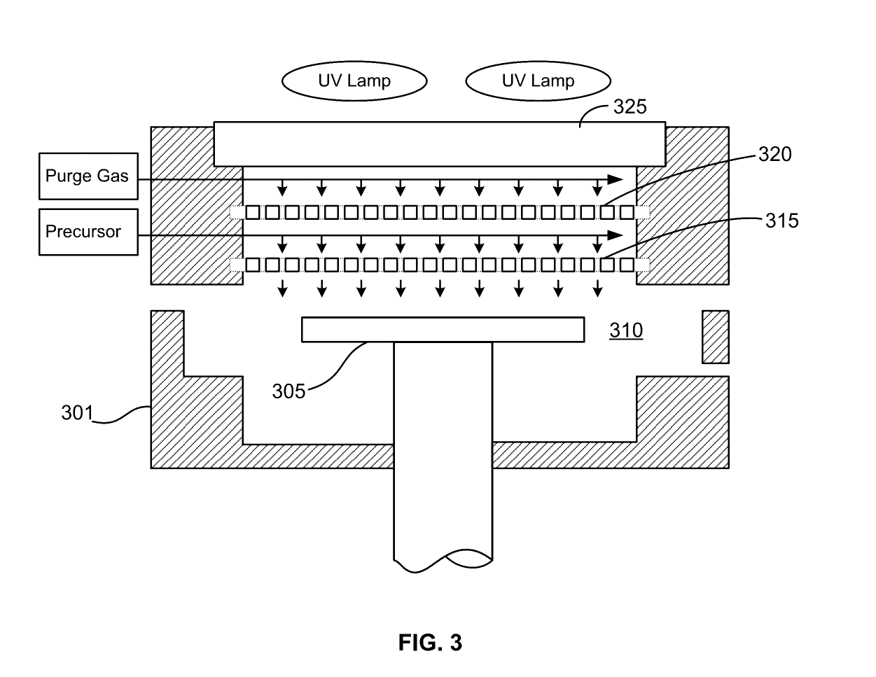

Several operations described herein involve the exposure to ultraviolet radiation which may be referred to herein as UV-light. FIG. 3 shows a schematic representation of a substrate processing chamber which may be used to perform selected operations of low-k dielectric treatment process 101. The patterned substrate with the low-k dielectric layer 220 may be placed on a heatable substrate pedestal 305 inside substrate processing chamber 301. The region above the patterned substrate is substrate processing region 310. An upper showerhead 320 and a lower showerhead 315 are disposed above substrate processing region 310. A UV-light transparent vacuum window 325 is disposed above upper showerhead 320 to allow UV-light to pass through from UV lamps (shown) into substrate processing chamber 301. Upper showerhead 320 and lower showerhead 315 may also be transparent to UV-light according to embodiments and are configured to allow precursors to pass through pores. UV-light transparent vacuum window 325, upper showerhead 320 and/or lower showerhead 315 may be quartz or another transparent material according to embodiments. A purge gas may be flowed into the region above upper showerhead 320 and the purge gas may flow through upper showerhead 320. At the same time, a carbon-and-hydrogen-containing precursor, a silicon-carbon-nitrogen-and-hydrogen-containing precursor or a nitrogen-and-hydrogen-containing precursor may be flowed into the region between lower showerhead 315 and upper showerhead 320 in operations 110 and 130 respectively. The same substrate processing chamber may be used for both operations to simplify the process flow. The purge gas may prevent the reactive precursor from entering the region above upper showerhead 320 and depositing material on UV-light transparent vacuum window 325. The purge gas may essentially guide the reactive precursor through lower showerhead 315 to react, as desired, on the patterned substrate. The UV light wavelength may be between 200 nm and 500 nm or between 200 nm and 400 nm according to embodiments.

The examples described herein involve the preparation of a long trench above a low-aspect ratio via in a dual-damascene structure. Generally speaking the structure may involve only one level and the low-k dielectric layer may have long trenches and/or vias on that one level according to embodiments. For the purposes of description herein and claim recitations below, a via is simply a low-aspect ratio gap (as viewed from above). The term “gap” covers all holes in a low-k dielectric described herein. Generally speaking, underlying copper layer 201 may be any underlying conducting layer or metal layer in embodiments.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “silicon oxide” of the patterned substrate is predominantly SiO₂ but may include concentrations of other elemental constituents such as, e.g., nitrogen, hydrogen and carbon. In some embodiments, silicon oxide portions etched using the methods disclosed herein consist essentially of silicon and oxygen. Exposed “silicon nitride” of the patterned substrate is predominantly Si₃N₄ but may include concentrations of other elemental constituents such as, e.g., oxygen, hydrogen and carbon. In some embodiments, silicon nitride portions described herein consist essentially of silicon and nitrogen. Exposed “titanium nitride” of the patterned substrate is predominantly titanium and nitrogen but may include concentrations of other elemental constituents such as, e.g., oxygen, hydrogen and carbon. In some embodiments, titanium nitride portions described herein consist essentially of titanium and nitrogen. The low-k dielectric may be “silicon oxycarbide” which is predominantly silicon, oxygen and carbon but may include concentrations of other elemental constituents such as, e.g., nitrogen and hydrogen. In some embodiments, silicon oxycarbide portions described herein consist essentially of silicon, oxygen and carbon. Exposed “silicon carbon nitride” of the patterned substrate is predominantly silicon, carbon and nitrogen but may include concentrations of other elemental constituents such as, e.g., oxygen and hydrogen. In some embodiments, silicon carbon nitride portions described herein consist essentially of silicon, carbon and nitrogen. “Copper” of the patterned substrate is predominantly copper but may include concentrations of other elemental constituents such as, e.g., oxygen, nitrogen, hydrogen and carbon. In some embodiments, copper portions described herein consist essentially of copper. Analogous definitions for other metals (e.g. Cobalt) will be understood from this copper definition.

The term “gap” is used throughout with no implication that the patterned geometry has a large horizontal aspect ratio. Viewed from above the surface, gaps may appear circular, oval, polygonal, rectangular, or a variety of other shapes. The term “trench” is defined as a large aspect ratio gap with a long dimension (viewed from above) at least ten times a short dimension (also viewed from above). The long dimension does not have to be linear, e.g., a trench may be in the shape of a moat around an island of material, in which case the long dimension is the circumference. The term “via” is used to refer to a low aspect ratio gap which may or may not be filled with metal to form a vertical electrical connection. As used herein, a conformal deposition or etch process refers to a generally uniform formation or removal of material on a surface in the same shape as the surface, i.e., the surface of the formed layer or etched layer and the pre-formation or pre-etch surface are generally parallel. A person having ordinary skill in the art will recognize that the outer surface of a formed layer or the etched interface likely cannot be 100% conformal and thus the term “generally” allows for acceptable tolerances.

Having disclosed several embodiments, it will be recognized by those of skill in the art that various modifications, alternative constructions, and equivalents may be used without departing from the spirit of the disclosed embodiments. Additionally, a number of well-known processes and elements have not been described to avoid unnecessarily obscuring the present embodiments. Accordingly, the above description should not be taken as limiting the scope of the claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the embodiments and claims, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

1. A method of forming a patterned substrate, the method comprising:
placing the patterned substrate having a patterned low-k dielectric layer into a substrate processing region, wherein the patterned substrate comprises a gap through the patterned low-k dielectric layer to an underlying metal layer, wherein the gap has dielectric sidewalls in the patterned low-k dielectric layer;
flowing a carbon-and-hydrogen-containing precursor in the substrate processing region while shining UV-light onto the patterned low-k dielectric layer;
forming a conformal hermetic layer on the patterned substrate by flowing the carbon-and-hydrogen-containing precursor; and
depositing gapfill copper into the gap to form a conducting contact between the gapfill copper and the underlying metal layer.

2. The method of claim 1 wherein forming the conducting contact comprises depositing gapfill copper into the gap.

3. The method of claim 1 wherein the conformal hermetic layer comprises silicon, carbon and nitrogen.

4. The method of claim 1 wherein a thickness of the conformal hermetic layer is between 0.1 nm and 0.3 nm.

5. The method of claim 1 wherein the conformal hermetic layer is configured to prevent moisture from entering the dielectric sidewalls.

6. The method of claim 1 wherein the conformal hermetic layer is configured to prevent metal atoms from migrating into the dielectric sidewalls.

7. The method of claim 1 wherein flowing the carbon-and-hydrogen-containing precursor comprises flowing a silicon-carbon-and-hydrogen-containing precursor in the substrate processing region.

8. The method of claim 7 wherein flowing the silicon-carbon-and-hydrogen-containing precursor in the substrate processing region reduces a dielectric constant of the patterned low-k dielectric layer below 2.4.

9. A method of forming a gap in a low-k dielectric layer, the method comprising:
removing —OH groups from the low-k dielectric layer and replacing them with CxHy groups to reduce a dielectric constant of the low-k dielectric layer;
forming a conformal silicon-carbon-and-nitrogen-containing layer on a patterned substrate, wherein the patterned substrate comprises the gap above an underlying copper layer, wherein sidewalls of the gap comprise low-k dielectric material, wherein the conformal silicon-carbon-and-nitrogen-containing layer is configured to prevent diffusion of material into the low-k dielectric material; and
depositing a conductor into the gap to form an electrical contact between the conductor and the underlying copper layer.

10. The method of claim 9 further comprising removing a portion of the conformal silicon-carbon-and-nitrogen-containing layer disposed on the underlying copper layer before depositing the conductor into the gap.

11. The method of claim 9 wherein the conformal silicon-carbon-and-nitrogen-containing layer consists of silicon, carbon and hydrogen.

12. The method of claim 9 wherein the conductor comprises cobalt or copper.

13. The method of claim 9 wherein a width of the gap is less than 20 nm.

14. A method of forming a dual damascene structure, the method comprising:
forming a methylation layer on the dual damascene structure; and
forming a conformal silicon carbon nitride layer over a patterned substrate, wherein the patterned substrate comprises a trench and a via below the trench, wherein the via is above an underlying copper layer, wherein sidewalls of the trench and the via comprise low-k dielectric walls, and wherein the trench is fluidly coupled to the via and the conformal silicon carbon nitride layer forms a hermetic seal between the trench and the low-k dielectric walls.

15. The method of claim 14 wherein a width of the via is less than 50 nm.

16. The method of claim 14 wherein a width of the trench is less than 70 nm.
